(19) United States
(12) Patent Application Publication
(10) Pub. No.: US 2016/0187391 A1
(43) Pub. Date: Jun. 30, 2016

(54) ELECTRICAL CURRENT MAGNITUDE INDICATOR

(71) Applicants: HONG FU JIN PRECISION INDUSTRY (WuHan) CO., LTD., Wuhan (CN); HON HAI PRECISION INDUSTRY CO., LTD., New Taipei (TW)

(72) Inventors: XIN YE, Wuhan (CN); CHUN-SHENG CHEN, New Taipei (TW)

(21) Appl. No.: 14/699,726

(22) Filed: Apr. 29, 2015

(30) Foreign Application Priority Data
Dec. 31, 2014 (CN) 201410848035.0

(51) Int. Cl. G01R 19/00; H01R 13/66; H01R 13/717

(52) U.S. Cl. CPC G01R 19/0092; H01R 13/7175; H01R 13/6683

(57) ABSTRACT

An electrical current magnitude indicator includes a housing, a USB plug, and a current detecting circuit. The current detecting circuit includes a current detecting chip, a resistor, and a light emitting diode (LED). The current detecting chip includes an input pin coupled to a power pin of the USB plug, an output pin, and a ground pin coupled to ground. The current detecting chip receives an input power signal from the power pin, converts the input power signal to an output power signal, and outputs the output power signal through the output pin through the resistor to activate the LED. The brightness of the activated LED varies depending on the output power signal, with the output power signal depending upon the input power signal, with a larger input power signal resulting in brighter light emitted by LED.

### FIELD

The subject matter herein generally relates to sensors and indicators.

### BACKGROUND

Today, USB components are broadly applied in serial communication solutions and are important. However, the charging capability of USB device cannot be directly viewed.

### BRIEF DESCRIPTION OF THE DRAWINGS

Implementations of the present technology will now be described, by way of example only, with reference to the attached figures.

FIG. 1 is a diagrammatic view of an exemplary embodiment of an electrical current magnitude indicator.

FIG. 2 is a circuit diagram of a USB plug and a current detecting circuit of the electrical current magnitude indicator of FIG. 1.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts have been exaggerated to better illustrate details and features of the present disclosure.

Several definitions that apply throughout this disclosure will now be presented.

The term “coupled” is defined as connected, whether directly or indirectly through intervening components, and is not necessarily limited to physical connections. The connection can be such that the objects are permanently coupled or releasably coupled. The term “comprising,” when utilized, means “including, but not necessarily limited to”; it specifically indicates open-ended inclusion or membership in the so-described combination, group, series and the like.

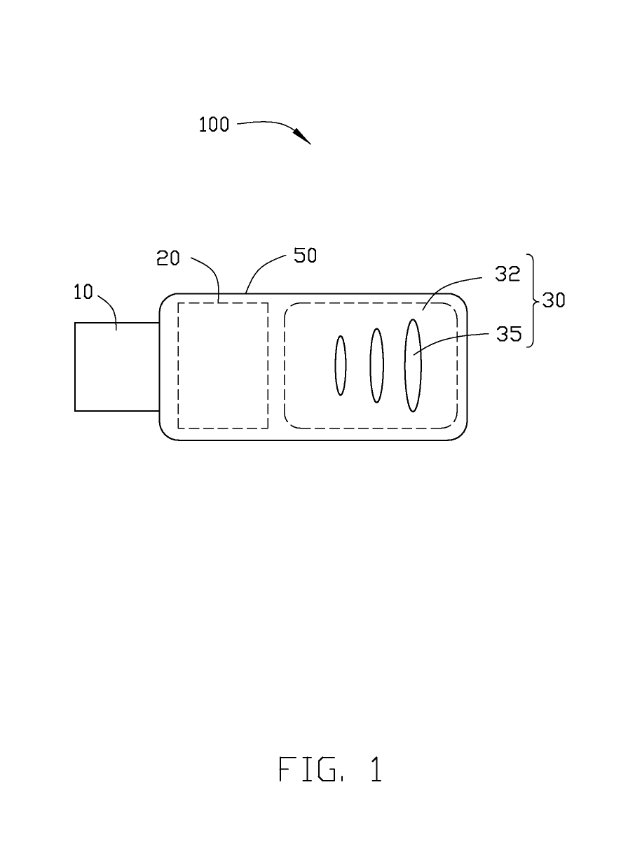

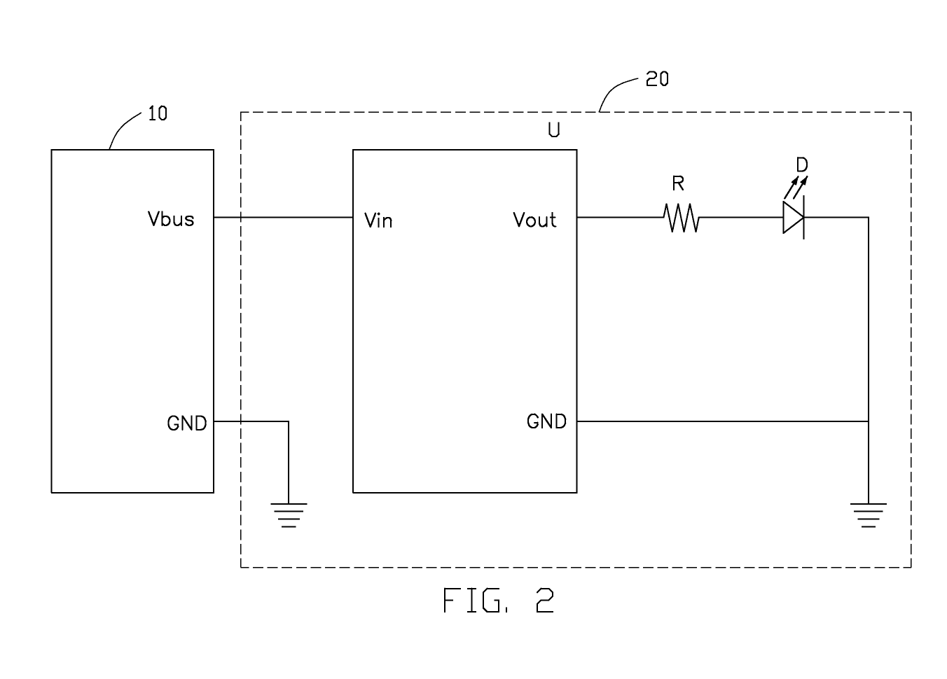

Referring to FIGS. 1 and 2, an embodiment of a current detecting device 100 includes a USB plug 10, a housing 50, and a current detecting circuit 20 received in the housing 50. The current detecting device 100 is utilized to detect a current of a USB connector unit under test (USB UUT) through a USB jack.

The housing 50 includes an outer shell 32. The outer shell 32 defines a defined interior space and includes a plurality of defined transparent shell areas 35. In the illustrated embodiment, the number of the plurality of transparent shell areas 35 is three.

The USB plug 10 extends from the housing 50 and is engagable with the USB jack. The USB plug 10 includes a power pin Vbus, and a ground pin GND. The current detecting circuit 20 is positioned substantially within the housing 50 defined interior space. The current detecting circuit 20 includes a current detecting chip U, a resistor R, and a light emitting diode (LED) D. The current detecting chip U includes an input pin Vin, an output pin Vout, and a ground pin GND. The input pin Vin of the current detecting chip U is coupled to the power pin Vbus of the USB plug 10. The ground pin GND of the USB plug 10 is coupled to ground. The output pin Vout of the current detecting chip U is coupled to an anode of the LED D through the resistor R and a cathode of the LED D is grounded. The ground pin GND of the current detecting chip U is grounded. The LED D is positioned within the housing 50 to allow light emitted from the LED D to pass through one or more of the one or more defined transparent shell areas 35.

When detecting the amount of current of the USB UUT, the USB plug 10 is received in the USB UUT through the jack and the input pin Vin of the current detecting chip U receives an input power signal from the USB UUT through the power pin Vbus of the USB plug 10. The current detecting chip U converts the input power signal to an output power signal and outputs the output power signal through the output pin Vout of the current detecting chip U. The LED D receives the output power signal from the output pin Vout of the current detecting chip U through the resistor R. In this process, the output power signal activates the LED D. Brightness of the activated LED D varies depending on the output power signal, with the output power signal depending upon the input power signal, with a larger input power signal resulting in brighter light emitted by LED D. In other words, a greater output power signal causes the LED D to shine brighter, indicating that the current detecting chip U is receiving a greater input power signal and the USB UUT has faster charging capability.

In the illustrated embodiment, the LED D is fixed to a left side of the transparent shell areas 35. When the LED D emits light which is visible through only one of the transparent shell areas 35 positioned close to the LED D, this indicates that the current detecting chip U is receiving small power signal and the USB UUT has slow charging capability. When the LED D emits light which is visible through two of the transparent shell areas 35 positioned close to the LED D, this indicates that the current detecting chip U is receiving great power signal and the charging capabilities of the USB UUT have increased. When the LED D emits light which is visible through all of the transparent shell areas 35, this indicates that the current detecting chip U is receiving the greatest power signal and the USB UUT has fastest-charging capabilities.

It is believed that the discussed embodiments and their advantages will be understood from the foregoing description, and it will be apparent that various changes may be made thereto without departing from the disclosure or sacrificing all of its material advantages. The embodiments discussed herein do not limit the following claims.

What is claimed is:

1. An electrical current magnitude indicator, the indicator comprising:
a housing having an outer shell, the outer shell defining a defined interior space and including one or more defined transparent shell areas;
a universal serial bus (USB) plug extending from the housing and engagable with a USB jack, the USB plug having a power pin and a ground pin coupled to ground; and
a current detecting circuit positioned substantially within the housing defined interior space, the current detecting circuit having:
a current detecting chip with an input pin connected to the power pin of the USB plug and a ground pin connected to ground;
a resistor connected an output pin of the current detecting chip; and
a light emitting diode connected to the resistor and positioned within the housing to allow light emitted from the light emitting diode to pass through one or more of the one or more defined transparent shell areas;
wherein, the power pin of the USB plug receives an input power signal from the USB jack when the USB plug is engaged with the USB jack;
wherein, the current detecting chip is configured to receive the input power signal from the power pin, convert the input power signal to an output power signal and outputs the output power signal through the output pin through the resistor to activate the light emitting diode; and
wherein, brightness of the activated light emitting diode varies depending on the output power signal, with the output power signal depending upon the input power signal, with a larger input power signal resulting in brighter light emitted by light emitting diode.

2. The electrical current magnitude indicator of claim 1, wherein the number of the transparent shell areas is three.

3. The electrical current magnitude indicator of claim 2, wherein the greatest output power signal causes the light emitting diode to emit light which is visible through all of the transparent shell areas, indicating that the current detecting chip receives greatest power signal.

4. The electrical current magnitude indicator of claim 1, wherein the light emitting diode comprises an anode coupled to the output pin of the current detecting chip through the resistor, and a cathode coupled to the ground.
